(19) United States
(12) Patent Application Publication
(10) Pub. No.: US 2008/0119057 A1
(43) Pub. Date: May 22, 2008

(54) METHOD OF CLUSTERING SEQUENTIAL PROCESSING FOR A GATE STACK STRUCTURE

(75) Inventors: THAI CHENG CHUA, Cupertino, CA (US); Christopher Sean Olsen, Fremont, CA (US); Cory Czarnik, Saratoga, CA (US); Giuseppina Conti, Oakland, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS,INC.

(21) Appl. No.: 11/561,870

(22) Filed: Nov. 20, 2006

(51) Int. Cl. H01L 21/31

(52) U.S. Cl. 438/763; 257/E21.24

(57) ABSTRACT

A method of forming a gate dielectric comprising silicon and oxygen is provided. The gate dielectric may also include nitrogen or another high k material. In one aspect, forming the gate dielectric includes annealing a substrate in an oxidizing atmosphere to form a silicon oxide layer, depositing a silicon nitride layer or a high k layer on the silicon oxide layer by a vapor deposition, oxidizing an upper surface of the silicon nitride layer or high k layer, and then annealing the substrate. The gate dielectric may be formed within an integrated processing system.

### BACKGROUND OF THE INVENTION

1. Field of the Invention

Embodiments of the present invention generally relate to a method of forming a gate dielectric. More particularly, embodiments of the invention relate to a method of forming a gate dielectric comprising silicon and oxygen within an integrated processing system.

2. Description of the Related Art

Integrated circuits are composed of many, e.g., millions, of devices such as transistors, capacitors, and resistors. Transistors, such as field effect transistors, typically include a source, a drain, and a gate stack. The gate stack typically includes a substrate, such as a silicon substrate, a gate dielectric, such as silicon dioxide, SiO₂, on the substrate, and a gate electrode, such as polycrystalline silicon, on the gate dielectric.

As integrated circuit sizes and the sizes of the transistors thereon decrease, the gate drive current required to increase the speed of the transistor has increased. Because the drive current increases as the gate capacitance increases, and capacitance is inversely proportional to the gate dielectric thickness, decreasing the dielectric thickness is one method of increasing the drive current.

Attempts have been made to reduce the thickness of SiO₂ gate dielectrics below 20 Å. However, it has been found that the use of thin SiO₂ gate dielectrics below 20 Å often results in undesirable effects on gate performance and durability. For example, a dopant from a doped gate electrode can penetrate through a thin SiO₂ gate dielectric into the underlying silicon substrate. Also, there is typically an increase in gate leakage, i.e., tunneling, with thin dielectrics that increases the amount of power consumed by the gate.

Silicon oxynitride (SiON or SiOₓN_{y}) films have been developed as alternatives to SiO₂ gate dielectrics. The silicon oxynitride films are typically formed by thermal nitridation or plasma nitridation of SiO₂ films. Incorporating nitrogen into the SiO₂ films blocks dopant penetration into the underlying silicon substrate, reduces current leakage, and allows the use of a thicker gate dielectric. However, the high temperatures used in thermal nitridation can result in the diffusion of the nitrogen through the gate dielectric to an underlying silicon channel interface, and excess nitrogen at the silicon channel interface can degrade the channel mobility and cause negative bias temperature instability (NBTI). Similarly, the plasma processing conditions used in plasma nitridation can generate nitrogen ions having an energy sufficient to penetrate the gate dielectric to the underlying silicon channel interface.

Therefore, there remains a need for a method of forming improved gate dielectrics.

### SUMMARY OF THE INVENTION

Embodiments of the present invention generally provide a method of forming a gate dielectric on a substrate. The gate dielectric comprises silicon and oxygen and may also include nitrogen or a high k material such as a hafnium silicate, hafnium oxide, or hafnium lanthanum silicate. In one aspect, the gate dielectric comprises a thin silicon oxide layer on a silicon substrate and a silicon nitride or high k layer on the silicon oxide layer, wherein the silicon nitride or high k layer has an oxidized upper surface.

In one embodiment, a method of forming a gate dielectric comprising silicon and oxygen on a substrate comprises conducting a first annealing a substrate comprising silicon in an oxidizing atmosphere to form a silicon oxide layer on the substrate and depositing a silicon nitride layer or a high k layer selected from the group consisting of a hafnium oxide layer, a hafnium silicate layer, and a hafnium lanthanum silicate layer on the silicon oxide layer by chemical vapor deposition or atomic layer deposition. The silicon nitride layer or high k layer is exposed to a plasma comprising oxygen to oxidize an upper surface of the silicon, and then a second annealing the substrate is conducted.

In another embodiment, a method of forming a gate dielectric comprising silicon and oxygen on a substrate comprises introducing a substrate comprising silicon into an integrated processing system, conducting a first annealing the substrate in an oxidizing atmosphere in a first chamber of the integrated processing system to form a silicon oxide layer on the substrate and depositing a silicon nitride layer or a high k layer selected from the group consisting of a hafnium oxide layer, a hafnium silicate layer, and a hafnium lanthanum silicate layer on the silicon oxide layer by chemical vapor deposition or atomic layer deposition in a second chamber of the integrated processing system. The silicon nitride layer or high k layer is exposed to a plasma comprising oxygen to oxidize an upper surface of the silicon in a third chamber of the integrated processing system, and then a second annealing the substrate is conducted in a chamber of the integrated processing system.

In a further embodiment, a method of forming a gate dielectric comprising silicon and oxygen on a substrate comprises introducing a substrate comprising silicon into an integrated processing system and conducting a first annealing the substrate in an oxidizing atmosphere in a first chamber of the integrated processing system to form a silicon oxide layer on the substrate. A silicon nitride layer is deposited on the silicon oxide layer by atomic layer deposition in a second chamber of the integrated processing system. The silicon nitride layer is exposed to a plasma comprising oxygen to oxidize an upper surface of the silicon nitride layer in a third chamber of the integrated processing system, and then a second annealing the substrate is conducted in a chamber of the integrated processing system.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flow chart depicting an embodiment of the invention.

FIG. 2 is a flow chart depicting another embodiment of the invention.

FIGS. 3A-3D depict schematic cross-sectional views of a substrate structure at different stages of a process sequence according to an embodiment of the invention.

FIG. 4 is a top schematic view of an integrated processing system that may be used to perform embodiments of the invention.

### DETAILED DESCRIPTION

Embodiments of the present invention provide a method of forming a gate dielectric comprising silicon and oxygen. In one aspect, the gate dielectric comprises a thin silicon oxide layer, a silicon nitride or high dielectric constant (k) layer on the thin silicon oxide, and an oxidized upper surface of the silicon nitride or high k layer. As defined herein, a high k layer has a dielectric constant of greater than about 4, such as between about 4 and about 30.

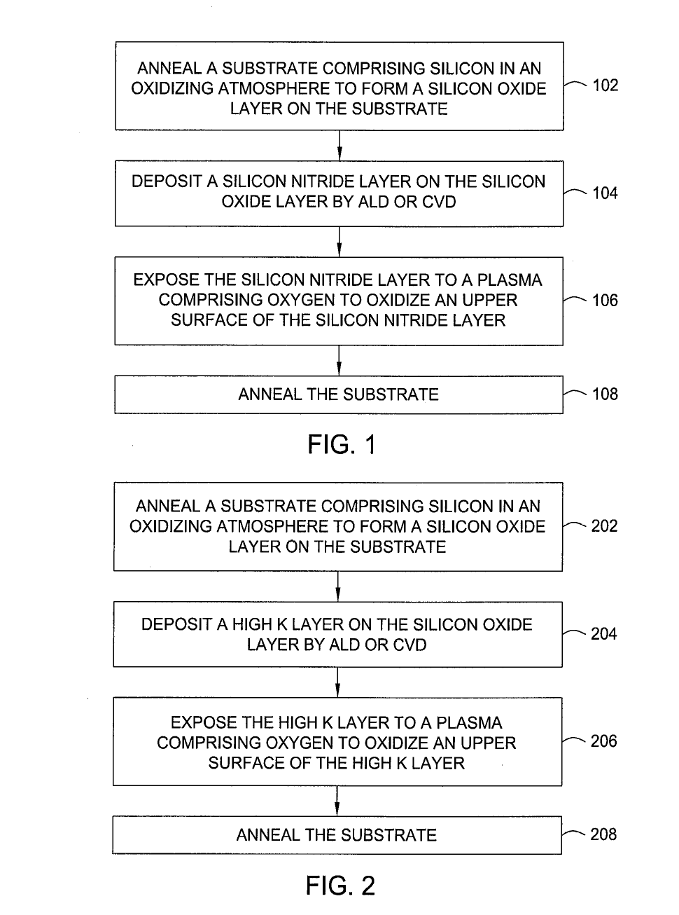

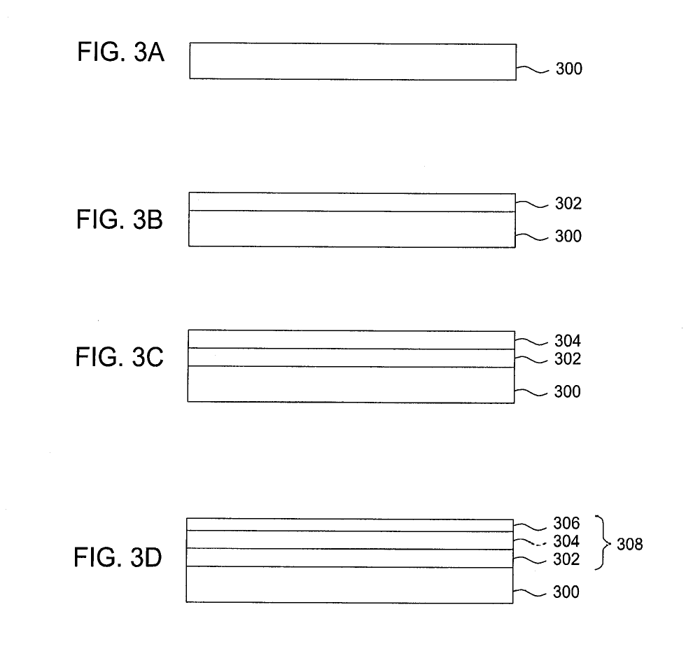

Embodiments of the invention will be described briefly with respect to the flow charts of FIGS. 1 and 2 and will be further described below with respect to FIGS. 3A-3D.

In one embodiment, a substrate comprising silicon is annealed in an oxidizing atmosphere to form a silicon oxide layer on the substrate, as shown in step 102 of FIG. 1. A silicon nitride layer is deposited on the silicon oxide layer by chemical vapor deposition (CVD) or atomic layer deposition (ALD), as shown in step 104. The silicon nitride layer is exposed to a plasma comprising oxygen, as shown in step 106. Exposing the silicon nitride layer to a plasma comprising oxygen oxidizes an upper surface of the silicon nitride layer. The substrate, which has the silicon oxide layer, silicon nitride layer, and oxidized upper surface of the silicon nitride layer thereon, is then annealed, as shown in step 108.

In another embodiment, a substrate comprising silicon is annealed in an oxidizing atmosphere to form a silicon oxide layer on the substrate, as shown in step 202 of FIG. 2. A high k layer is deposited on the silicon oxide layer by chemical vapor deposition (CVD) or atomic layer deposition (ALD), as shown in step 204. The high k layer is exposed to a plasma comprising oxygen, as shown in step 206. Exposing the high k layer to a plasma comprising oxygen oxidizes an upper surface of the high k layer. The substrate, which has the silicon oxide layer, silicon nitride layer, and oxidized upper surface of the high k layer thereon, is then annealed, as shown in step 208.

FIGS. 3A-3D show an example of a substrate structure at different stages of processing according to the embodiments of FIGS. 1 and 2. FIG. 3A shows a substrate 300 that comprises silicon. The substrate may be a 200 mm or 300 mm substrate or another substrate suitable for semiconductor or flat panel display processing. Preferably, the substrate is cleaned to remove any native oxide on its surface before the substrate is annealed in an oxidizing atmosphere. The native oxide may be removed by treating the substrate with a wet cleaning process, such as cleaning the substrate in a hydrofluoric acid (HF) solution. The solution may have a concentration of about 0.1 to about 10.0 weight percent HF and be used at a temperature of about 20° C. to about 30° C. In an exemplary embodiment, the solution has about 0.5 weight percent of HF and a temperature of about 25° C. A brief exposure of the substrate to the solution may be followed by a rinse step in deionized water.

FIG. 3B shows the substrate 300 having a thin silicon oxide layer 302 thereon. The thin silicon oxide layer 302 may be a silicon dioxide (SiO₂) layer. The thin silicon oxide layer 302 is formed by annealing the substrate 300 in an oxidizing atmosphere, as described above with respect to steps 102 and 202. The oxidizing atmosphere may be an ambient of oxygen (O₂), hydrogen (H₂) and O₂, H₂ and nitrous oxide (N₂O), O₂ and an inert gas, or combinations thereof. The silicon oxide film may have a thickness of about 2 Å to about 10 Å, for example. In one embodiment, the substrate may be exposed to the oxidizing atmosphere at a substrate temperature between about 700° C. and about 1100° C. and at a pressure between about 0.1 Torr and about 800 Torr for a time of between about 1 second and about 180 seconds. Preferably, the temperature is between about 750° C. and about 1000° C., and the pressure is between about 0.5 Torr and about 50 Torr.

FIG. 3C shows a layer 304 that is deposited on the silicon oxide layer 302. Layer 304 may be a silicon nitride layer deposited by CVD or ALD, as described above with respect to step 104 of FIG. 1, or a high k layer deposited by CVD or ALD, as described above with respect to step 204 of FIG. 2.

A layer 304 of silicon nitride may be deposited by CVD or ALD from a gas mixture comprising a silicon source and a nitrogen source. Before the layer 304 of silicon nitride is deposited, the silicon oxide layer 302 may be exposed to a plasma of nitrogen, such as in a decoupled plasma nitridation (DPN) process at between about 10 mTorr and about 50 mTorr, with a pulsed source N₂ plasma at 25-900 effective Watts for about 5 to about 120 seconds to incorporate a small amount of nitrogen into the silicon oxide layer 302, as it has been observed that such a process enhances the nucleation of a silicon nitride layer deposited by ALD on the silicon oxide layer.

The silicon nitride layer may have a thickness of between about 2 Å and about 10 Å. The silicon source may be silane (SiH₄), disilane (Si₂H₆), dichlorosilane (SiH₂Cl₂), hexachlorodisilane (Si₂Cl₆), or a combination thereof, for example. An example of a nitrogen source that may be used is ammonia (NH₃).

Exemplary CVD processing conditions that may be used for depositing the silicon nitride layer include a substrate temperature of between about 300° C. and about 600° C., a chamber pressure of between about 1 Torr and about 100 Torr, a silicon source flow rate of between about 5 sccm and about 100 sccm, and a nitrogen source flow rate of between about 5 sccm and about 10 slm. The CVD process may be a low pressure thermal CVD process or a plasma-enhanced CVD process. The CVD process may be a continuous process or a pulsed CVD process in which the precursors are co-flowed and pulsed into the deposition chamber. An example of a CVD chamber that may be used to deposit the silicon nitride layer is a SiNgene LPCVD chamber, available from Applied Materials, Inc. of Santa Clara, Calif.

As defined herein, “atomic layer deposition” refers to the sequential introduction of two or more reactive compounds to deposit a layer of material on a substrate surface. In one aspect, a silicon precursor and a reactant are sequentially pulsed into a chamber in an ALD process to deposit a silicon nitride layer. An example of a chamber that may be used is a 300 mm ALD Gemini chamber available from Applied Materials, Inc. of Santa Clara, Calif. The silicon precursor may be introduced into the chamber with a flow rate from about 1 sccm to about 300 sccm, preferably from about 10 sccm to about 100 sccm for a gas precursor and from about 5 mg/min to 500 mg/min for a liquid precursor. The reactant may be introduced into the chamber with a flow rate from about 100 sccm to about 10,000 sccm or higher, preferably greater than about 500 sccm, such as from about 500 sccm to about 3,000, more preferably, from about 1,000 sccm to about 2,000 sccm.

The silicon precursor may also be a nitrogen-containing compound, such as an aminosilane. Specific aminosilanes that are useful silicon precursors are alkylaminosilanes with the chemical formula of (RR′N)₄₋ₙSiHₙ, wherein R and R′ are independently hydrogen, methyl, ethyl, propyl, butyl, pentyl or aryl and n=0, 1, 2 or 3. In one embodiment, R is hydrogen and R′ is an alkyl group, such as methyl, ethyl, propyl, butyl or pentyl, for example, R′ is a butyl group, such as tertiarybutyl and n is 2. In another embodiment, R and R′ are independently alkyl groups, such as methyl, ethyl, propyl, butyl and pentyl or an aryl group. Silicon precursors useful for the deposition processes described herein include (^{t}Bu(H)N)₃SiH, (^{t}Bu(H)N)₂SiH₂, (^{t}Bu(H)N)SiH₃, (ⁱPr(H)N)₃SiH, (ⁱPr(H)N)₂SiH₂, (^{l}Pr(H)N)SiH₃, and derivatives thereof. In one embodiment, the silicon precursor is bis(tertiarybutylamino)silane ((^{t}Bu(H)N)₂SiH₂ or BTBAS). In other embodiments, the silicon precursor may be an alkylaminosilane with the chemical formula of (RR′N)₄₋ₙSiR″ₙ, wherein R and R′ are independently hydrogen, methyl, ethyl, propyl, butyl, pentyl, or aryl, R″ is independently hydrogen, alkyl (e.g., methyl, ethyl, propyl, butyl or pentyl), aryl or halogen (e.g., F, Cl, Br or I) and n=0, 1, 2 or 3.

Reactants that may be used in the deposition processes described herein include hydrogen (H₂), silanes, germanes, boranes, hydrocarbons and/or alkyls, phosphines, amines, hydrazines, azides, derivatives thereof and combinations thereof. Silanes include silane (SiH₄), disilane (Si₂H₆), trisilane (Si₃H₈), dichlorosilane (Cl₂SiH₂), hexachlorodisilane (Si₂Cl₆), alkylsilanes (e.g., MeSiH₃) and derivatives thereof. Germanes include germane (GeH₄), digermane (Ge₂H₆), trigermane (Ge₃H₈), alkylgermanes (e.g., MeGeH₃) and derivatives thereof. Boranes include borane (BH₃), diborane (B₂H₆) and alkylboranes (e.g., Et₃B), adducts thereof and derivatives thereof. Hydrocarbons and/or alkyls include methane (CH₄), ethane (C₂H₆), propane (C₃H₈), butane (C₄H₁₀), ethene (C₂H₄), ethyne (C₂H₂), propene (C₃H₆), propyne (C₃H₄), butane (C₄H₈), butyne (C₄H₆) and derivatives thereof. Phosphines include phoshine (PH₃), methylphosphine (MePH₂), dimethylphosphine (Me₂PH) and derivatives thereof. Amines and hydrazines include (H₃Si)₃N, (Me₃Si)₃N, Me₃N, Et₃N, H₂NNH₂, Me(H)NNH₂, Me₂NNH₂, Me₂NNMe₂, ^{t}BuNN^{t}Bu, and derivatives thereof. In a preferred embodiment, the reactant is hydrogen, silane, disilane, or a combination thereof.

Further description of ALD processes that may be used to deposit the silicon nitride layers described herein is provided in commonly assigned U.S. patent application Ser. No. 10/898,547, filed Jul. 23, 2004, entitled “Low Thermal Budget Silicon Nitride Formation for Advance Transistor Fabrication,” and published as U.S. Patent Publication No. 2006/0019032, which is incorporated by reference herein.

By depositing a thin silicon oxide layer 302 and then a layer 304 of silicon nitride by chemical vapor deposition or atomic layer deposition on the substrate 300 rather than plasma nitriding or thermally annealing a thick silicon oxide layer to form a silicon oxynitride layer, contamination of the underlying silicon substrate 300 with nitrogen is minimized.

In another embodiment, a layer 304 of a high k material, such as a hafnium-containing material, e.g., a hafnium oxide layer, a hafnium silicate layer, or a hafnium lanthanum silicate layer may be deposited by CVD or ALD on the silicon oxide layer 302. The hafnium oxide may have the formula HfOₓ or HfO₂. The hafnium silicate may have the formula HfSi_{y}Oₓ and may be a mixture of hafnium oxide (HfOₓ or HfO₂) and silicon oxide (SiOₓ or SiO₂) or a single phase HfSiO₄ material. The layer 304 of the high k material may have a thickness of between about 10 Å and about 60 Å.

An ALD process for depositing a hafnium oxide layer may include exposing a substrate to a pulse of a hafnium precursor introduced into a chamber alone or in combination with a carrier gas for a time period, such as in a range from about 0.1 seconds to about 5 seconds. A pulse of purge gas is then introduced into the chamber to purge or otherwise remove any residual hafnium precursor or by-products. Next, a pulse of oxidizing gas is introduced into the chamber. The oxidizing gas may include a mixture of several oxidizing agents, such as water vapor and oxygen. A pulse of purge gas is again introduced into the chamber to purge or otherwise remove any residual oxidizing gas or by-products.

An ALD process for depositing a hafnium silicate layer may include sequentially pulsing the following gases into a chamber: a hafnium precursor, a purge gas, an oxidizing gas, a purge gas, a silicon precursor, a purge gas, an oxidizing gas, and a purge gas. Alternatively, an ALD process for depositing a hafnium silicate layer may include providing to a chamber an overlapping pulse of a hafnium precursor and a pulse of a silicon precursor followed by a pulse of purge gas, a pulse of oxidizing gas, and a pulse of purge gas.

Further description of ALD processes that may be used to deposit the hafnium oxide and hafnium silicate layers described herein is provided in commonly assigned U.S. patent application Ser. No. 11/127,767, filed May 12, 2005, entitled “Apparatuses and Methods for Atomic Layer Deposition of Hafnium-Containing High-k Dielectric Materials,” and published as U.S. Patent Publication No. 2005/0271813, which is incorporated by reference herein.

Exemplary hafnium precursors for CVD or ALD include hafnium compounds containing ligands such as halides, alkylaminos, cyclopentadienyls, alkyls, alkoxides, derivatives thereof or combinations thereof. Hafnium halide compounds useful as hafnium precursors may include HfCl₄, Hfl₄, and HfBr₄. Hafnium alkylamino compounds useful as hafnium precursors include (RR′N)₄Hf, where R or R′ are independently hydrogen, methyl, ethyl, propyl or butyl. Hafnium precursors useful for depositing hafnium-containing materials include (Et₂N)₄Hf, (Me₂N)₄Hf, (MeEtN)₄Hf, (^{t}BuC₅H₄)₂HfCl₂, (C₅H₅)₂HfCl₂, (EtC₅H₄)₂HfCl₂, (Me₅C₅)₂HfCl₂, (Me₅C₅)HfCl₃, (ⁱPrC₅H₄)₂HfCl₂, (ⁱPrC₅H₄)HfCl₂, (^{t}BuC₅H₄)₂HfMe₂, (acac)₄Hf, (hfac)₄Hf, (tfac)₄Hf, (thd)₄Hf, (NO₃)₄Hf, (^{t}BuO)₄Hf, (ⁱPrO)₄Hf, (EtO)₄Hf, (MeO)₄Hf or derivatives thereof. Preferably, hafnium precursors used during the deposition processes herein include HfCl₄, (Et₂N)₄Hf or (Me₂N)₄Hf.

Exemplary silicon precursors useful for depositing hafnium silicate layers by CVD or ALD include silanes, alkylaminosilanes, silanols or alkoxy silanes, for example, silicon precursors may include (Me₂N)₄Si, (Me₂N)₃SiH, (Me₂N)₂SiH₂, (Me₂N)SiH₃, (Et₂N)₄Si, (Et₂N)₃SiH, (MeEtN)₄Si, (MeEtN)₃SiH, Si(NCO)₄, MeSi(NCO)₃, SiH₄, Si₂H₆, SiCl₄, Si₂Cl₆, MeSiCl₃, HSiCl₃, Me₂SiCl₂, H₂SiCl₂, MeSi(OH)₃, Me₂Si(OH)₂, (MeO)₄Si, (EtO)₄Si or derivatives thereof. Other alkylaminosilane compounds useful as silicon precursors include (RR′N)₄₋ₙSiHₙ, where R or R′ are independently hydrogen, methyl, ethyl, propyl or butyl and n=0-3. Other alkoxy silanes may be described by the generic chemical formula (RO)₄₋ₙSiLₙ, where R=methyl, ethyl, propyl or butyl and L=H, OH, F, Cl, Br or I and mixtures thereof. Preferably, silicon precursors used during the deposition process herein include (Me₂N)₃SiH, (Et₂N)₃SiH, (Me₂N)₄Si, (Et₂N)₄Si or SiH₄.

Exemplary CVD processing conditions that may be used for depositing a hafnium oxide layer include a substrate temperature of between about 200° C. and about 700° C., a chamber pressure of between about 1 Torr and about 200 Torr, a hafnium precursor flow rate of between about 5 mg/min and about 500 mg/min sccm, and an oxygen precursor flow rate of between about 5 sccm and about 1000 sccm. The CVD process may be a conventional CVD process or a plasma-enhanced CVD process. The CVD process may be a continuous process or a pulsed CVD process in which the precursors are co-flowed and pulsed into the deposition chamber.

Exemplary CVD processing conditions that may be used for depositing a hafnium silicate layer include a substrate temperature of between about 200° C. and about 700° C., a chamber pressure of between about 1 Torr and about 200 Torr, a hafnium precursor flow rate of between about 5 mg/min and about 500 mg/min, a silicon precursor flow rate of between about 5 mg/min and about 500 mg/min, and an oxidizing gas flow rate of between about 5 sccm and about 1000 sccm. The CVD process may be a conventional CVD process or a plasma-enhanced CVD process. The CVD process may be a continuous process or a pulsed CVD process in which the precursors are co-flowed and pulsed into the deposition chamber.

Returning to FIG. 3D, an oxidized upper surface layer 306 is formed on layer 304 by exposing layer 304 to a plasma comprising oxygen. The plasma comprising oxygen may be generated from an oxygen source such as O₂, NO, N₂O, or combinations thereof. The plasma may be provided by applying between about 25 watts and about 1000 watts of power. The plasma may be produced using RF power, microwave power, or a combination thereof. The plasma may be produced using a quasi-remote plasma source, an inductive plasma source, a radial line slotted antenna (RLSA) source, or other plasma sources. The plasma may be continuous or pulsed. The O₂ partial pressure during the exposure of the layer 304 to the plasma may be between about 1 mTorr and about 100 mTorr. The oxygen source may be introduced into the chamber at a flow rate of between about 1 sccm and about 1000 sccm at a chamber pressure of between about 5 mTorr and about 3000 mTorr for between about 3 seconds and about 120 seconds to provide a thin oxidized upper surface layer 306 having a thickness of between about 0.2 Å and about 5 Å.

The thin oxidized upper surface layer 306 is particularly useful when the layer 304 is a layer comprising nitrogen, such as a silicon nitride layer, as it minimizes the formation of nitrogen-silicon bonds when a polysilicon layer is deposited thereon as a gate electrode. Nitrogen-silicon bonds can cause a flatband voltage shift, particularly in PMOS devices. Oxidizing the upper surface of the silicon nitride layer is also desirable because it raises the band gap of the silicon nitride layer and thus lowers the leakage across the gate dielectric.

After the oxidized upper surface layer 306 is formed on layer 304, the substrate 300, including layers 302, 304, and 306 thereon, is annealed to stabilize the plasma treatment and improve the interface between the substrate 300 and the silicon oxide layer 302. In one embodiment, annealing the substrate comprises exposing the substrate to a lightly oxidizing ambient atmosphere, such as a low pressure oxidizing ambient, such as a low pressure O₂ or O₂ diluted in N₂ ambient, wherein the O₂ partial pressure is between about 1 mTorr and about 100 Torr. The substrate may be annealed at a substrate temperature between about 800° C. and about 1100° C. for between about 5 seconds and about 180 seconds. The O₂ may be introduced into the annealing chamber at a flow rate of between about 2 sccm and about 5000 sccm, such as about 500 sccm. In one embodiment, O₂ is provided at about 500 sccm while maintaining the temperature at about 1000° C. and a pressure of about 0.1 Torr for about 15 seconds.

In another embodiment, annealing the substrate comprises exposing the substrate to an inert gas, such as nitrogen, argon, or a combination thereof, at a temperature of between about 800° C. and about 1100° C.

Typically, annealing the substrate completes the formation of a gate dielectric 308 which comprises the silicon oxide layer 302, layer 304, and the oxidized upper surface layer 306. A gate electrode material, such as a polysilicon layer, may then be deposited on the gate dielectric. The polysilicon layer may have a thickness of between about 500 Å and about 5000 Å.

Integrated Processing Sequence

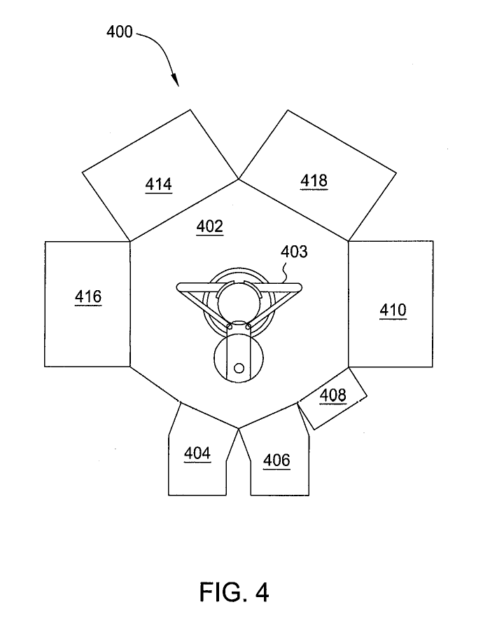

In further embodiments, a gate dielectric comprising silicon and oxygen is formed on a substrate in an integrated processing system, such as an integrated semiconductor processing system, in a method in which the substrate is not removed from the integrated processing system until after the gate dielectric is formed. An example of an integrated processing system 400 that may be used is the Gate Stack CENTURA® system, available from Applied Materials, Inc. of Santa Clara, Calif., which is shown schematically in FIG. 4. The integrated processing system 400 may include a central transfer chamber 402, transfer robot 403, load locks 404, 406, a cool down chamber 408, a CVD or ALD chamber 410, a plasma processing chamber 414, a rapid thermal processing (RTP) chamber 416, and a CVD or ALD chamber 418.

The processing conditions for embodiments in which the gate dielectric is formed in an integrated processing system may be the same as the processing conditions provided above for the formation of a gate dielectric. An embodiment in which a gate dielectric is formed in an integrated processing system will be summarized below with respect to FIG. 4.

A substrate comprising silicon is introduced into the integrated processing system 400 via a load lock 404 or 406. The load lock 404 or 406 may have a vacuum or nitrogen purged environment. Preferably, the substrate is cleaned to remove native oxide before it is introduced into the integrated processing system. The substrate may be transferred from the load lock 404 or 406 by the transfer robot 403 through the central transfer chamber 402, which may also have a vacuum or nitrogen purged environment, to the rapid thermal processing chamber 416. Examples of rapid thermal processing chambers that may be used include a RADIANCE® chamber or a RadiancePlus RTP chamber, both of which are available from Applied Materials, Inc. of Santa Clara, Calif. The substrate is annealed in an oxidizing atmosphere in the rapid thermal processing chamber 416 to form a silicon oxide layer on the substrate. The substrate is then transferred to CVD or ALD chamber 410 or CVD or ALD chamber 418, and a silicon nitride layer or high k layer, as described above, is deposited on the silicon oxide layer by CVD or ALD. An example of a CVD chamber that may be used to deposit a silicon nitride layer is a SiNgen® LPCVD chamber. The substrate is then transferred to plasma processing chamber 414 and exposed to a plasma comprising oxygen to oxidize an upper surface of the silicon nitride layer or high k layer. An example of a plasma processing chamber 414 that may be used is a decoupled plasma nitridation chamber (DPN), such as the DPN CENTURA® chamber, available from Applied Materials, Inc. of Santa Clara, Calif. However, the plasma processing chamber 414 may be another pulsed quasi-remote RF DPN chamber or a chamber comprising a magnetron or RLSA microwave plasma source.

The substrate is then transferred to a rapid thermal processing (RTP) chamber 416. The RTP chamber may be a RADIANCE® chamber or a RadiancePlus RTP chamber, both of which are available from Applied Materials, Inc. of Santa Clara, Calif. Alternatively, chamber 416 may be a conventional furnace. The substrate is annealed in chamber 416 to complete the formation of the gate dielectric. The substrate may then be transferred to CVD or ALD chamber 410 or CVD or ALD chamber 418 for the deposition of a gate electrode material, such as a polysilicon layer, on the gate dielectric. An example of a CVD chamber 410 or 418 that may be used to deposit a polysilicon layer is a POLYgen LPCVD chamber, available from Applied Materials, Inc. of Santa Clara, Calif.

Forming the gate dielectrics described herein in an integrated processing system, which provides a vacuum or nitrogen-purged sub-vacuum environment, results in good control of the interfaces between the layers of the gate dielectrics and between the gate dielectric and the overlying and underlying silicon layers, as the surfaces of the various layers are not exposed to the outside atmosphere which may cause the formation of native oxides on the layers or the contamination of the substrate. For example, carbon contaminants have been found at the interface between the silicon oxide layer and the silicon nitride layer of gate dielectrics that are not formed in integrated processing systems. It is believed that the temperatures typically used to deposit the silicon nitride film, e.g., 300-600° C., are not sufficient to bake off carbon contaminants on the silicon oxide layer from the atmosphere or processing equipment, for example, before the deposition of the silicon nitride layer on the silicon oxide layer. Thus, embodiments of the invention provide a method of forming gate dielectrics that minimizes the presence of contaminants, such as carbon, that may degrade the dielectric.

While the foregoing is directed to embodiments of the present invention, other and further embodiments of the invention may be devised without departing from the basic scope thereof, and the scope thereof is determined by the claims that follow.

What is claimed is:

1. A method of forming a gate dielectric comprising silicon and oxygen on a substrate, comprising:
conducting a first annealing a substrate comprising silicon in an oxidizing atmosphere to form a silicon oxide layer on the substrate;
depositing a silicon nitride layer or a high k layer selected from the group consisting of a hafnium oxide layer, a hafnium silicate layer, and a hafnium lanthanum silicate layer on the silicon oxide layer by chemical vapor deposition or atomic layer deposition;
exposing the silicon nitride layer or high k layer to a plasma comprising oxygen to oxidize an upper surface of the silicon nitride layer or high k layer; and then
conducting a second annealing the substrate.

2. The method of claim 1, wherein the silicon oxide layer has a thickness of between about 2 Å and about 10 Å.

3. The method of claim 2, wherein a silicon nitride layer is deposited to a thickness of between about 2 Å and about 10 Å on the silicon oxide layer.

4. The method of claim 3, further comprising exposing the silicon oxide layer to a plasma of nitrogen before depositing the silicon nitride layer, and wherein the silicon nitride layer is deposited by atomic layer deposition.

5. The method of claim 2, wherein a high k layer selected from the group consisting of a hafnium oxide layer, a hafnium silicate layer, and a hafnium lanthanum silicate layer is deposited to a thickness between about 10 Å and about 60 Å on the silicon oxide layer.

6. The method of claim 1, further comprising removing native oxide from the substrate before the first annealing.

7. The method of claim 1, further comprising depositing a polysilicon layer on the oxidized upper surface of the silicon nitride layer or high k layer.

8. The method of claim 1, wherein the oxidized upper surface of the silicon nitride layer or high k layer has a thickness of between about 0.2 Å and about 5 Å.

9. The method of claim 8, wherein the exposing the silicon nitride layer or high k layer to a plasma comprising oxygen comprises applying between about 25 watts and about 1000 watts of power.

10. A method of forming a gate dielectric comprising silicon and oxygen on a substrate, comprising:
introducing a substrate comprising silicon into an integrated processing system;
conducting a first annealing the substrate in an oxidizing atmosphere in a first chamber of the integrated processing system to form a silicon oxide layer on the substrate;
depositing a silicon nitride layer or a high k layer selected from the group consisting of a hafnium oxide layer, a hafnium silicate layer, and a hafnium lanthanum silicate layer on the silicon oxide layer by chemical vapor deposition or atomic layer deposition in a second chamber of the integrated processing system,
exposing the silicon nitride layer or high k layer to a plasma comprising oxygen to oxidize an upper surface of the silicon nitride layer or high k layer in a third chamber of the integrated processing system; and then
conducting a second annealing the substrate in a chamber of the integrated processing system.

11. The method of claim 10, wherein the silicon nitride layer or high k layer is deposited by atomic layer deposition.

12. The method of claim 10, wherein the silicon nitride layer or high k layer is deposited by chemical layer deposition.

13. The method of claim 10, wherein the exposing the silicon nitride layer or high k layer to a plasma comprising oxygen comprises applying between about 25 watts and about 1000 watts of power.

14. The method of claim 10, wherein the second annealing completes formation of the gate dielectric, and the substrate is not removed from the integrated processing system until after the gate dielectric is formed.

15. The method of claim 14, further comprising depositing a polysilicon layer on the gate dielectric in the integrated processing system.

16. A method of forming a gate dielectric comprising silicon and oxygen on a substrate, comprising:
introducing a substrate comprising silicon into an integrated processing system;
conducting a first annealing the substrate in an oxidizing atmosphere in a first chamber of the integrated processing system to form a silicon oxide layer on the substrate;
depositing a silicon nitride layer on the silicon oxide layer by atomic layer deposition in a second chamber of the integrated processing system;
exposing the silicon nitride layer to a plasma comprising oxygen to oxidize an upper surface of the silicon nitride layer in a third chamber of the integrated processing system; and then
conducting a second annealing the substrate in a chamber of the integrated processing system.

17. The method of claim 16, further comprising exposing the silicon oxide layer to a plasma of nitrogen in the integrated processing system before depositing the silicon nitride layer.

18. The method of claim 17, wherein the silicon nitride layer is deposited at a temperature between about 300° C. and about 600° C.

19. The method of claim 17, further comprising removing native oxide from the substrate before the substrate is introduced into the integrated processing system.

20. The method of claim 19, further comprising depositing a polysilicon layer on the oxidized upper surface of the silicon nitride layer in a fourth chamber of the integrated processing system.
